(19) United States
(12) Patent Application Publication
(10) Pub. No.: US 2018/0138209 A1
(43) Pub. Date: May 17, 2018

(54) SEMICONDUCTOR SUBSTRATE WITH METALLIC DOPED BURIED OXIDE

(71) Applicant: GLOBALFOUNDRIES INC., GRAND CAYMAN (KY)

(72) Inventors: Wen Liu, South Burlington, VT (US); Criag M. Bocash, Winooski, VT (US); Carole D. Graas, Ballston Spa, NY (US); Fen Chen, Morgan Hill, CA (US)

(73) Assignee: GLOBALFOUNDRIES INC., GRAND CAYMAN (KY)

(21) Appl. No.: 15/351,678

(22) Filed: Nov. 15, 2016

(51) Int. Cl. H01L 27/12; H01L 23/373; H01L 21/3115; H01L 21/762

(52) U.S. Cl. CPC H01L 27/1211; H01L 27/1203; H01L 23/373; H01L 23/3731; H01L 21/76251; H01L 23/3736; H01L 21/31155

(57) ABSTRACT

An SOI substrate includes a metallic doped isolation (i.e., buried oxide) layer. Doping of the isolation layer increases its thermal conductivity, which improves heat conduction and decreases the susceptibility of devices formed on the substrate to temperature-induced deterioration and/or failure over time. The amount as well as the configuration of the doping can be tailored to specific circuit architectures.

### BACKGROUND

The present application relates generally to semiconductor devices, and more particularly to metallic doped silicon-on-insulator (SOI) substrates having improved thermal conduction and fin field effect transistor devices formed on such SOI substrates.

Fully-depleted devices such as fin field effect transistors (FinFETs) are candidates to enable scaling of next generation gate lengths to 14 nm and below. Fin field effect transistors (FinFETs) present a three-dimensional architecture where the transistor channel is raised above the surface of a semiconductor substrate, rather than locating the channel at or just below the surface. With a raised channel, the gate can be wrapped over the top and the sides of the channel, which provides improved electrostatic control of the device.

The manufacture of FinFETs typically leverages a self-aligned process to produce extremely thin fins, e.g., 20 nm wide or less, on the surface of a substrate using selective-etching techniques. A gate structure is then deposited to contact multiple surfaces of each fin to form a multi-gate architecture.

The characteristics of FinFET-based devices compare favorably with traditional transistor architectures. For example, a 16 nm FinFET has a higher gate density and about 25% more drive capability compared with a 20 nm planar transistor. However, the confined geometry associated with the FinFET architecture also generates 25-30% more power density and an attendant increase in localized heat, which can negatively affect device performance and reliability. Moreover, the insulating characteristics of SOI substrates, which are ubiquitous in FinFET design, exacerbate the challenges associated with thermal budget and operating temperature-driven failure.

Accordingly, it would be advantageous to develop a FinFET architecture that mitigates the operating temperature effects associated with these high power density structures.

### SUMMARY

In accordance with embodiments of the present application, a FinFET is constructed on an SOI substrate having a doped isolation (i.e., buried oxide) layer. Metallic doping of the isolation layer increases its thermal conductivity, which improves heat conduction and decreases the susceptibility of the device to temperature-induced deterioration and/or failure over time. The amount as well as the configuration of the doping can be tailored to specific circuit architectures.

An example SOI substrate includes a handle portion, an isolation layer disposed over the handle portion, and a semiconductor layer disposed over the isolation layer defining an interface boundary with the isolation layer. The isolation layer includes a dopant such that the doped isolation layer exhibits a thermal conductivity greater than that of an undoped corresponding isolation layer.

A method of manufacturing such an SOI substrate includes forming an isolation layer over a handle portion of a semiconductor substrate, forming a semiconductor layer over the isolation layer, and incorporating a dopant into the isolation layer to increase the thermal conductivity of the isolation layer.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a schematic cross-sectional view of a semiconductor-on-insulator substrate;

FIGS. 2A-2D are schematic illustrations of a wafer bonding process for forming a semiconductor-on-metallic-doped insulator substrate with a dopant localized to a specified depth within the insulator layer;

FIGS. 3A-3D are schematic illustrations of a wafer bonding process for forming a semiconductor-on-metallic-doped insulator substrate with a dopant incorporated throughout the insulator layer;

FIGS. 4A-4E are schematic illustrations of an ion-implantation and wafer bonding process for forming a semiconductor-on-metallic-doped insulator substrate with a dopant localized to an intermediate depth within the insulator layer;

FIGS. 5A-5E are schematic illustrations of an ion-implantation and wafer bonding process for forming a semiconductor-on-metallic-doped insulator substrate with a dopant localized to plural intermediate depths within the insulator layer;

FIGS. 6A-6E are schematic illustrations of an ion-implantation process for forming locally-doped semiconductor-on-metallic-doped insulator substrates according to various embodiments;

FIG. 7 is a schematic illustration of a hybrid semiconductor-on-metallic-doped insulator substrate having globally-doped and locally-doped regions;

FIG. 8 is a schematic illustration of a hybrid semiconductor-on-metallic-doped insulator substrate including a row of doped regions;

FIG. 9 is a schematic illustration of a hybrid semiconductor-on-metallic-doped insulator substrate including a double row of doped regions;

FIG. 10 is a plot of current versus voltage at various temperatures for SOI substrates having metallic-doped isolation layers;

FIG. 11 is a plot showing modeled results of the effects of doping on substrate temperature; and

FIG. 12 is a perspective view of a FinFET device formed on a semiconductor-on-metallic-doped insulator substrate at an intermediate stage of fabrication.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts. It is noted that the drawings are provided for illustrative purposes and, as such, may not be drawn to scale.

In the following description, numerous specific details are set forth, such as particular structures, components, materials, dimensions, processing steps and techniques, in order to provide an understanding of the various embodiments of the present application.

However, it will be appreciated by one of ordinary skill in the art that the various embodiments of the present application may be practiced without these specific details. In other instances, well-known structures or processing steps have not been described in detail in order to avoid obscuring the present application.

As an alternative to a conventional bulk silicon wafer platform for integrated circuit (IC) manufacture, SOI (silicon-on-insulator or semiconductor-on-insulator) substrates have been embraced by the microelectronics industry. SOI substrates are composite structures that include two semiconductor layers separated by an isolation layer. Compared to bulk silicon substrates, SOI substrates provide a number of advantages to circuit designers, including faster switching speeds, greater resistance to radiation effects, higher component packing densities, smaller leakage currents and parasitic capacitances, and the avoidance of low-impedance paths between power supply rails, i.e., “SCR latch-up.”

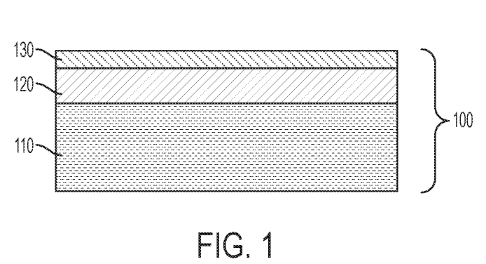

Referring to FIG. 1, a semiconductor-on-insulator substrate 100 includes, from bottom to top, a handle portion 110, an isolation layer 120, and a semiconductor layer 130. Handle portion 110 and semiconductor layer 130 may each comprise a silicon-containing material such as single crystal Si, polycrystalline Si, single crystal silicon germanium (SiGe), polycrystalline silicon germanium, silicon doped with carbon (Si:C), amorphous Si, as well as combinations and multi-layers thereof. As used herein, the term “single crystal” denotes a crystalline solid, in which the crystal lattice of the entire sample is substantially continuous and substantially unbroken to the edges of the sample with substantially no grain boundaries.

The SOI substrate 100 is not limited to silicon-containing materials. Each of the handle portion 110 and the semiconductor layer 130 may independently comprise other semiconductor materials, including germanium (Ge), III-V compound semiconductors such as GaAs, GaN, GaP, InAs, InSb, ZnSe, and ZnS, and II-VI compound semiconductors such as CdSe, CdS, CdTe, ZnSe, ZnS and ZnTe.

According to various embodiments, the handle portion 110 and the semiconductor layer 130 may comprise the same semiconductor material or different semiconductor materials. The handle portion 110 of an example semiconductor substrate may comprise (100)-oriented silicon or (111)-oriented silicon, for example, and the semiconductor layer 130 may comprise (100)-oriented silicon, single crystal SiGe or single crystal GaAs, although other materials and material combinations are contemplated. The thickness of the semiconductor layer 130 can be 10 to 100 nm, for example, although smaller and larger values are contemplated.

SOI substrate 100 may have dimensions as typically used in the art. Example substrate diameters include, but are not limited to, 50, 100, 150, 200, 300 and 450 mm. The total substrate thickness may range from 250 microns to 1500 microns, although in particular embodiments the substrate thickness is in the range of 725 to 775 microns, which corresponds to thickness dimensions commonly used in silicon CMOS processing.

In the example of FIG. 1, the SOI structure includes a bulk silicon handle substrate 110, an isolation layer 120 disposed over and in contact with the handle substrate 110, and a semiconductor layer 130 disposed over and in contact with the isolation layer 120. The isolation layer 120 between the handle portion 110 and the semiconductor layer 130 is often referred to as a buried oxide (BOX) layer. The thickness of the isolation layer 120 may range from 30 to 300 nm, e.g., 30, 50, 100, 150, 200, 250 or 300 nm, including ranges between any of the foregoing values, although lesser and greater thicknesses may be used. The isolation layer 120 may include, for example, silicon dioxide (SiO₂). Alternatively, isolation layer 120 may include silicon nitride, silicon oxynitride, a low-k material, or any suitable combination of these materials.

Exemplary low-k materials include but are not limited to, amorphous carbon, fluorine-doped oxides, carbon-doped oxides, SiCOH or SiBCN. Commercially-available low-k dielectric products and materials include Dow Corning's SiLK™ and porous SiLK™, Applied Materials' Black Diamond™, Texas Instrument's Coral™ and TSMC's Black Diamond™ and Coral™. As used herein, a low-k material has a dielectric constant less than that of silicon oxide.

An SOI substrate can be formed using a variety of methods such as, for example, SiMOX or bonding methods known to those skilled in the art. According to various embodiments, a wafer bonding process for manufacturing SOI wafers includes physically uniting two single crystal semiconductor wafers. For instance, one of the wafers can be thermally oxidized to form the isolation layer and, after cleaning operations, bonded to the other. Bringing two hydrophilic surfaces (such as SiO₂) into direct contact can result in a strong interfacial bond. Following a thermal anneal at temperatures as high as 1100° C. (e.g., 1000° C.), the bond strength can be increased to that of bulk material. The outer surface of the composite wafer can be ground and polished to the desired thickness (e.g., 1-3 microns) using, for example, chemical mechanical polishing.

Chemical mechanical polishing (CMP) is a material removal process that uses both chemical reactions and mechanical force to remove material and planarize a surface. In general, the surface to be polished is brought into contact with a rotating pad whereupon a chemically reactive slurry containing an abrasive, such as alumina, deteriorates and progressively removes the exposed surface layer. In certain embodiments, the CMP process removes the majority of the handle portion one of the bonded substrates, leaving a thin semiconductor overlayer on the isolation layer, supported by a semiconductor substrate.

Optionally, an epitaxial layer for integrating electronic components can be formed on the thinner single crystal layer. The additional epitaxial layer, if provided, may be formed by chemical vapor deposition. For instance, a silicon epitaxial layer may be formed at deposition temperatures of ˜1000° C. using dichlorosilane (SiH₂Cl₂) as a source gas.

The terms “epitaxy,” “epitaxial” and/or “epitaxial growth and/or deposition” refer to the growth of a semiconductor material layer on a deposition surface of a semiconductor material, in which the semiconductor material layer being grown assumes the same crystalline habit as the semiconductor material of the deposition surface. For example, in an epitaxial deposition process, chemical reactants provided by source gases are controlled and the system parameters are set so that depositing atoms alight on the deposition surface and remain sufficiently mobile via surface diffusion to orient themselves according to the crystalline orientation of the atoms of the deposition surface. Therefore, an epitaxial semiconductor material has the same crystalline characteristics as the deposition surface on which it is formed. For example, an epitaxial semiconductor material deposited on a (100) crystal surface will take on a (100) orientation.

A further example wafer bonding method can be performed in conjunction with a layer transfer process where, by way of example, a gallium arsenide surface to be bonded is cleaved from a source wafer of gallium arsenide. In such a process, a single crystal wafer of gallium arsenide (GaAs) is ion implanted, e.g., with hydrogen, to a desired depth to define a thin layer of gallium arsenide to be transferred. The implanted wafer is then pre-bonded to the isolation layer of a support substrate such as an oxidized silicon substrate. The pre-bonded assembly is heated to cause eruption of the hydrogen-rich plane and cleavage of the defined gallium arsenide layer from the gallium arsenide wafer. The support substrate with the transferred layer can then be heated to improve the bonding between the substrate and the transferred layer. The excess support substrate can be removed and the gallium arsenide layer polished to form an SOI structure. The gallium arsenide source wafer and the excess support substrate can each be recycled back into the process.

According to various embodiments, the thermal conductivity of an SOI substrate can be increased by incorporating a metallic dopant, i.e., impurity, into the isolation layer. Introduction of the dopant atoms can be performed before or after defining the SOI structure. Increasing the thermal conductivity of the SOI substrate facilitates heat transfer and heat dissipation, which can improve the performance and reliability of SOI-based devices. Example dopants include C, Al, Si, Ge, Ta, W, Mo, and alloys thereof, including SiC, AlN and TaSi, for example.

Within a locally-doped region, the spatial distribution of one or more dopants within the isolation layer 120 can be homogeneous or non-homogeneous. Further, according to various embodiments, and as illustrated with respect to several exemplary methods, spatial non-homogeneity of a dopant can independently vary in each of three dimensions, i.e., length, width and depth. As used herein, a depth of the isolation layer is defined with reference to a top surface thereof, i.e., from an interface boundary with the semiconductor material layer. In certain embodiments, the isolation layer includes one or more doped regions, which can be configured to accommodate particular device architectures, for example.

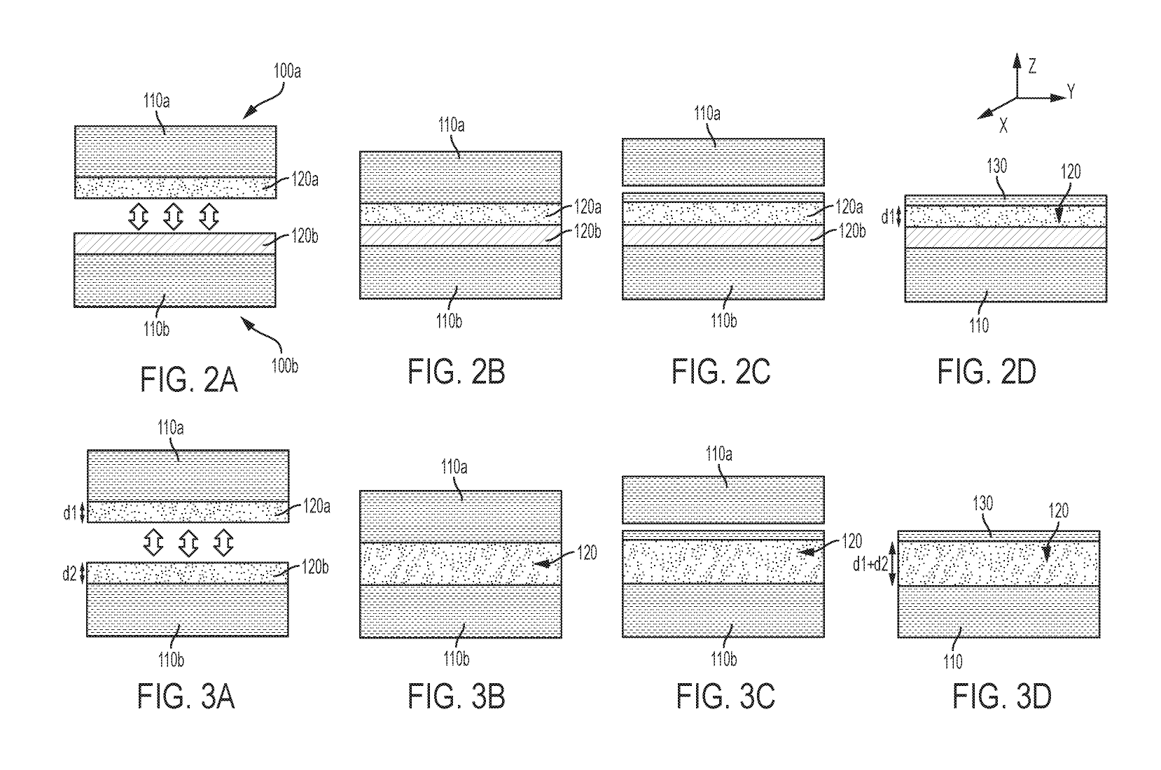

One example method of forming a semiconductor-on-metallic-doped insulator (SOMDI) wafer is illustrated in FIGS. 2A-2D. Isolation layer 120a of a first semiconductor substrate 100a having a handle portion 110a is doped and bonded to an undoped isolation layer 120b of a second semiconductor substrate 100b having a handle portion 110b. As shown in FIG. 2B, the isolation layer 120a of the first semiconductor substrate is brought into direct contact with the isolation layer 120b of the second semiconductor substrate. After bonding, excess handle portion 110a can be removed such as by grinding or polishing, as shown schematically in FIG. 2C.

In the instant embodiment, as illustrated in FIG. 2D, the dopant is localized within isolation layer 120 adjacent to semiconductor layer 130 where the dopant profile is spatially homogeneous over a depth (d1) corresponding to the thickness of the doped isolation layer 120a. In conjunction with the doped portion of the isolation layer, a portion of the isolation layer 120 adjacent to handle portion 110, corresponding to isolation layer 120b, remains undoped.

A further example method of forming an SOMDI substrate is illustrated in FIGS. 3A-3D. Doped isolation layer 120a of a first semiconductor substrate 100a having a handle portion 110a is bonded to a doped isolation layer 120b of a second semiconductor substrate 100b having a handle portion 110b. Within first and second semiconductor substrates 100a, 100b, the type as well as the concentration and distribution of dopant in the respective isolation layers 120a, 120b may be the same or different. As shown schematically in FIGS. 3B and 3C, substrates 100a, 100b are bonded and thinned in a manner described above with respect to FIG. 2.

As shown in FIG. 3D, the dopant is distributed throughout isolation layer 120 over a depth (d1+d2), corresponding to the combined thickness of doped isolation layers 120a, 120b. That is, dopant is incorporated throughout substantially the entire isolation layer 120.

The dopant concentration within the isolation layer 120 may be constant, or vary as a function of isolation layer thickness. For instance, the dopant concentration may be greatest at the interface between the isolation layer 120 and the semiconductor layer 130 and decrease with increased thickness. Alternatively, the dopant concentration may be greatest at the interface of the isolation layer 120 with handle substrate 110. In the latter case, the dopant concentration may increase from a minimum concentration at the interface between the isolation layer and the semiconductor layer 130 to a maximum at the interface of the isolation layer with the handle substrate 110.

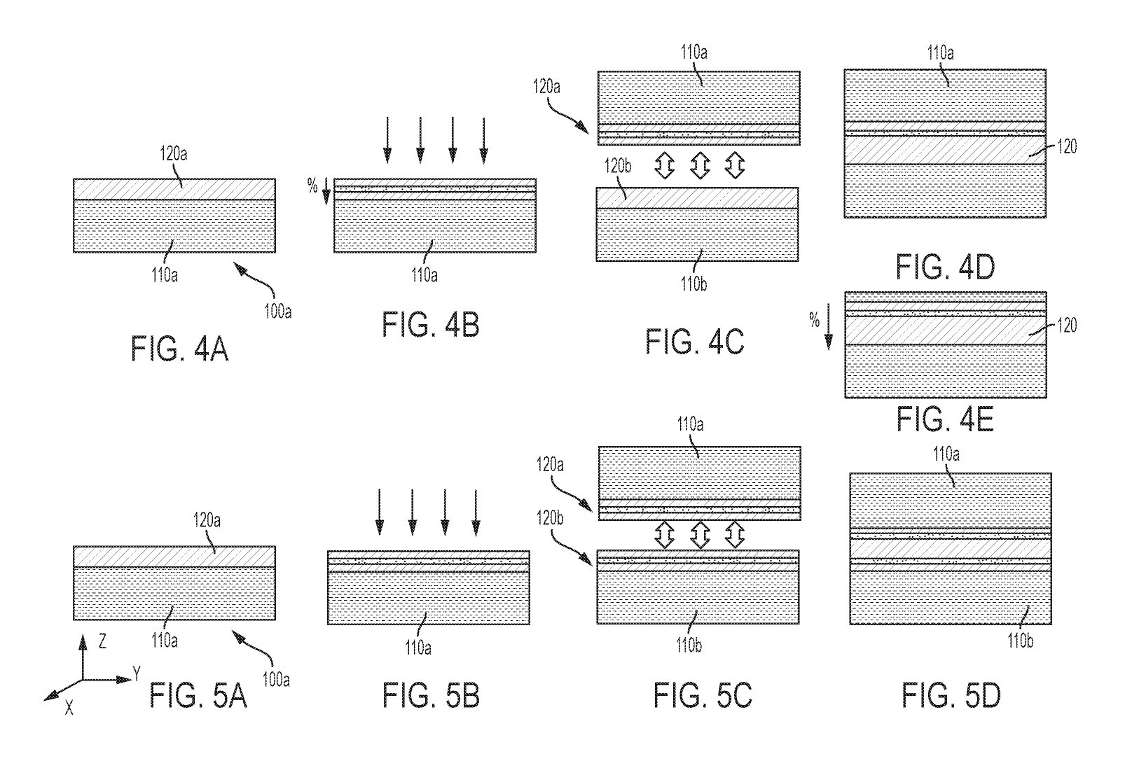

A variant of the embodiment illustrated in FIG. 2 is depicted in FIGS. 4A-4E. As shown schematically in FIGS. 4A and 4B, ion implantation can be used to introduce a dopant to a defined depth (or range of depths) within a first isolation layer 120a of a first semiconductor substrate 100a.

According to various embodiments, an implant dose for the dopant can range from 1×10¹⁴/cm² to 1×10¹⁶/cm², e.g., 1×10¹⁴, 2×10¹⁴, 5×10¹⁴, 1×10¹⁵, 2×10¹⁵, 5×10¹⁵ or 1×10¹⁶/cm², including ranges between any of the foregoing values. The ion implantation energy can range from 20 to 60 keV, e.g., 20, 40, or 60 keV, including ranges between any of the foregoing values. In various embodiments, the dopant profile in the thickness dimension of the isolation layer is defined by the ion implantation energy.

Referring to FIGS. 4C and 4D, doped isolation layer 120a of first semiconductor substrate 100a is bonded to an undoped isolation layer 120b of a second semiconductor substrate 100b. After bonding, excess handle portion 110a can be removed to form an SOMDI substrate as shown in FIG. 4E.

Expressed as a percentage of the thickness of the isolation layer 120 from a top surface thereof to the interface with the supporting handle substrate 110, as seen with reference to FIG. 4B, a dopant may be implanted to any suitable depth or range of depths, including plural depths or plural ranges depending on predetermined or desired thermal response. Referring to FIG. 4E, a dopant may be incorporated into the isolation layer 120 within a region extending from a first percentage of the thickness of the isolation layer, e.g., 5, 10, 20, 30, 40, 50, 60, 70, 80 or 90% of the thickness of the isolation layer to a second percentage of the thickness of the isolation layer, e.g., 10, 20, 25, 30, 40, 50, 60, 70, 75, 80, 90 or 95% of the thickness of the isolation layer, where the second percentage is greater than the first percentage. For example, a dopant may be incorporated into a region that extends from 10 to 20%, 25 to 50% and/or 70 to 95% of the isolation layer thickness.

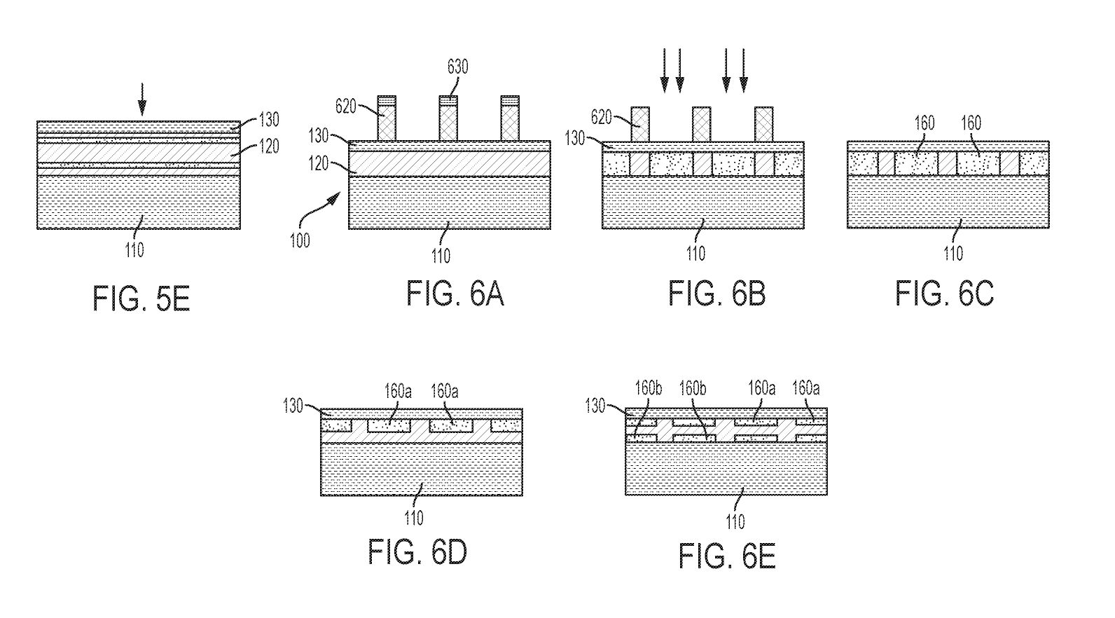

A variant of the embodiment illustrated in FIG. 4 is depicted in FIGS. 5A-5E. As seen in FIGS. 5A and 5B, ion implantation can be used to introduce a dopant to a defined depth (or range of depths) within each of first and second isolation layers 120a, 120b of first and second semiconductor substrates 100a, 100b. Referring to FIGS. 5C and 5D, doped isolation layer 120a of first semiconductor substrate 100a is bonded to the doped isolation layer 120b of a second semiconductor substrate 100b. After bonding and removal of excess handle portion 110a, the SOMDI substrate includes first and second globally-doped regions that are each defined over respective thickness ranges of the isolation layer 120.

In the embodiments illustrated in FIGS. 2-5, a dopant is incorporated into the isolation layer 120 globally, either throughout the thickness of the isolation layer or over a select, vertically discrete thickness range (or ranges) of the isolation layer. Referring to FIG. 6, according to various embodiments, a dopant may be incorporated into the isolation layer 120 locally, i.e., within one or more defined areas, such that the dopant is incorporated into the isolation layer over one or more horizontally discrete regions of the isolation layer. As will be appreciated, a locally incorporated dopant may also be incorporated into the isolation layer over a vertically discrete thickness range. Conventional lithography and etching processes may be used to define an area to be ion implanted with a dopant.

As used herein, “horizontal” refers to a general direction along a primary surface of a substrate, and “vertical” is a direction generally orthogonal thereto. Furthermore, “horizontal” and “vertical” are generally perpendicular directions relative to one another independent of orientation of the substrate in three-dimensional space. Thus, a vertically-discrete doped region adjoins at least one of an overlying or an underlying un-doped region.

For instance, a vertically-discrete doped region may be bounded by at least one of an overlying or an underlying un-doped region. A horizontally-discrete doped region adjoins an adjacent un-doped region such that, for example, a horizontally-discrete doped region is bounded by an adjacent un-doped region.

Referring to FIG. 6A, the lithography technique may include forming a hard mask layer 620 on the semiconductor layer 130 of an SOI substrate 100, applying a layer of photoresist 630 to an upper surface of the hard mask layer 620, exposing the photoresist to a desired pattern of radiation and developing the exposed photoresist using a resist developer. The pattern in the photoresist may then be transferred to the hard mask 620 using one or more etching techniques. Suitable etching techniques include, but are not limited to, reactive ion etching (RIE), ion bean etching, plasma etching or laser ablation. As seen with reference to FIG. 6B, the patterned photoresist may be consumed during the etch process, stripped after etching of the hard mask layer has been completed, or removed by ashing. The hard mask layer 620 may have a thickness of 10 to 100 nm, and comprise SiON, SiN or SiO₂, for example.

Referring to FIG. 6B, ion implantation into the unmasked isolation layer 120 may be performed. Ion implantation is used to independently control the dopant concentration and the dopant depth. Following ion implantation, the patterned hard mask is removed. Example engineered dopant profiles are shown schematically in FIGS. 6C-6E and FIGS. 7-9.

As illustrated in FIGS. 6C-6E, and according to various embodiments, the dopant profile is defined laterally within the isolation layer 120 by the patterned hard mask. Referring to FIG. 6C, horizontally discrete doped regions 160 extend completely through the isolation layer 120.

According to certain embodiments, the ion implantation energy can be adjusted to control the depth of the implantation profile. For example, referring to FIGS. 6D and 6E, plural doped regions extend only partially through the isolation layer 120. Referring to FIG. 6D, laterally adjacent first doped regions 160a extend into the isolation layer 120 from the interface with the semiconductor layer 130, such that a lower portion of the isolation layer is undoped.

Referring to FIG. 6E, first doped regions 160a extend into the isolation layer 120 from the interface with the semiconductor layer 130, i.e., to a first depth within the isolation layer 120, while second doped regions 160b extend into the isolation layer 120 from the interface with the handle portion 110, such that upper and lower portions of the isolation layer are intermittently doped while an intermediate region of the isolation layer is undoped. Second doped regions 160b include a plurality of discrete buried doped zones that extend from a second depth of the isolation layer to a third depth of the isolation layer greater than the second depth. As used herein, a “buried doped zone” or a “buried doped region” within the isolation layer is entirely spaced away from the interface with the semiconductor layer.

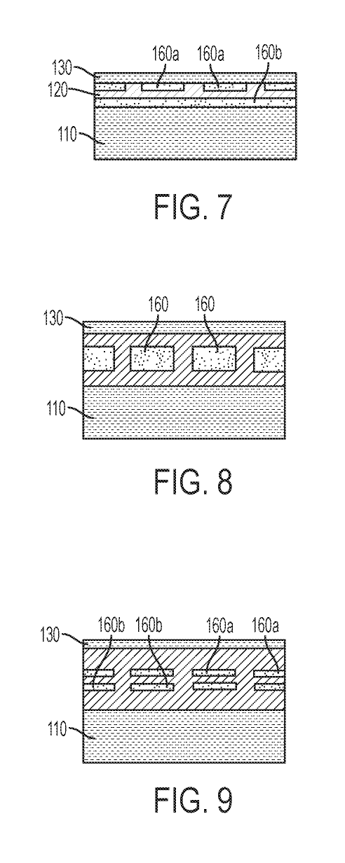

A hybrid doping profile is illustrated in FIG. 7. The SOMDI substrate 100 of FIG. 7 includes an isolation layer 120 having both a locally-doped upper region 160a, where a dopant defines a plurality of discrete doped zones that extend from the interface boundary to a first depth of the isolation layer, and a globally-doped lower region 160b that extends from a second depth of the isolation layer to a third depth of the isolation layer such that the upper region 160a is separated from the lower region 160b by an undoped region.

While the locally-doped region 160a and the globally-doped region 160b are each shown extending to a respective upper and lower surface of the isolation layer 120, it will be appreciated that the depth profile of the doped regions can extend from any suitable first depth to any suitable second depth of the isolation layer. Moreover, it will be appreciated that the dopant architecture of FIG. 7 can be reversed where the isolation layer comprises a globally-doped upper region and a locally-doped lower region.

In the structures shown in FIGS. 6 and 7, globally-doped and locally-doped regions within isolation layer 120 are immediately adjacent to either the handle portion 110 of the substrate or the semiconductor layer 130. Referring to FIGS. 8 and 9, shown are alternative architectures where, for example, locally-doped regions 160a are spaced away from the interface between the isolation layer 120 and the handle portion 110, and the interface between the isolation layer 120 and the semiconductor layer 130. A single row of locally-doped regions 160a is shown in FIG. 8, and a double row of locally-doped regions 160a is shown in FIG. 9.

The dopant concentration within the doped regions 160 may be constant or may vary, for example, as a function of isolation layer thickness. According to various embodiments, the dopant profile may be engineered to control the thermal conductivity of the isolation layer 120 and hence the effective thermal conductivity of the SOI substrate. Moreover, the dopant profile within the isolation layer can be configured to balance the properties of thermal conduction and electrical insulation.

It is known that the ratio of the electronic contribution of the thermal conductivity (κ) to the electrical conductivity (σ) of a metal is proportional to temperature according to the relationship κ/σ=LT, where L is the Lorenz number. It will be appreciated that uniform metallic doping of the entire isolation layer 120 will desirably increase the thermal conductivity of the isolation layer 120 but may undesirably increase the electrical conductivity of the isolation layer 120. A metallic dopant may be chosen from C, Al, Si, Ge, Ta, W, Mo, SiC, AlN and TaSi, as well as combinations thereof.

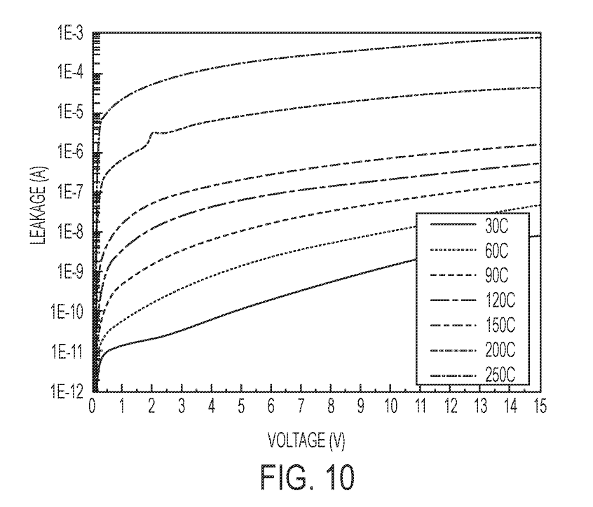

Current-voltage (I-V) traces for tungsten-doped isolation layers at various temperatures are shown in FIG. 10.

In the case of an isolation layer consisting essentially of silicon dioxide (SiO₂), which has an un-doped thermal conductivity of 1.3-1.4 W/mK, modeled data have shown that the incorporation of a dopant into the isolation layer can increase the effective thermal conductivity to 250 W/mK. In various embodiments, the effective thermal conductivity of an SOMDI substrate can range from 5 to 250 W/mK, e.g., 5, 10, 15, 20, 50, 100, 150, 200 or 250 W/mK, including ranges between any of the foregoing values. Through global and/or local doping of the isolation layer and the attendant increase in thermal conductivity, a significant reduction in device temperature can be realized.

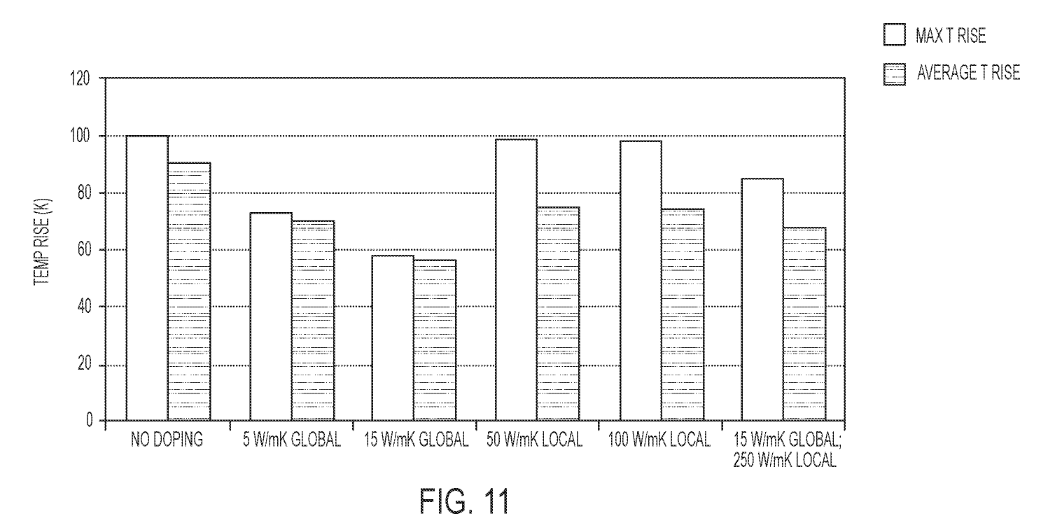

Thermal simulations have demonstrated that both the maximum temperature increase and the average temperature increase within a silicon dioxide isolation layer can be impacted by global and local doping profiles. Simulation results are summarized in FIG. 11.

For an undoped, 182 nm thick SiO₂ isolation layer, the maximum and average temperature rise from the 3-dimensional thermal model assuming 40 parallel silicon fins having a fin height of 28 nm and a fin length of 5000 nm overlying the isolation layer, are 100K and 90K, respectively.

Global (unmasked) doping into the near surface region of the isolation layer increases the thermal conductivity of the isolation layer to 5 W/mK and 15 W/mK, depending on the dopant concentration. The data in FIG. 11 show that global doping decreases both the maximum and the average temperature rise by as much as 50%.

Local doping into the near surface region of the isolation layer can form a local thermal pipe having a dramatically increased thermal conductivity. Depending on the dopant concentration, the effective thermal conductivity in the near surface region of the isolation layer is increased to 50 or 150 W/mK. Referring to FIG. 11, such localized doping has a less dramatic effect on the maximum temperature increase at the surface of the substrate due to the presence of undoped regions, although local doping can be used to minimize the dopant-induced increase in the electrical conductivity of the substrate.

The combination of local doping and global doping can be used to tailor both the thermal conductivity and the electrical resistivity of the SOMDI substrate. The formation of a locally-doped interfacial region between the isolation layer and the overlying semiconductor layer, for example, in conjunction with a deeper globally doped region can dampen the maximum temperature increase by as much as 20%, e.g., 5, 10 or 20%, including ranges between any of the foregoing values, and dampen the average temperature increase by as much as 40%, e.g., 10, 20, 30 or 40%, including ranges between any of the foregoing values, while maintaining good electrical insulating properties at the interface with the semiconductor layer 130, which can be used to form the fins of a fin field effect transistor (FinFET), for example.

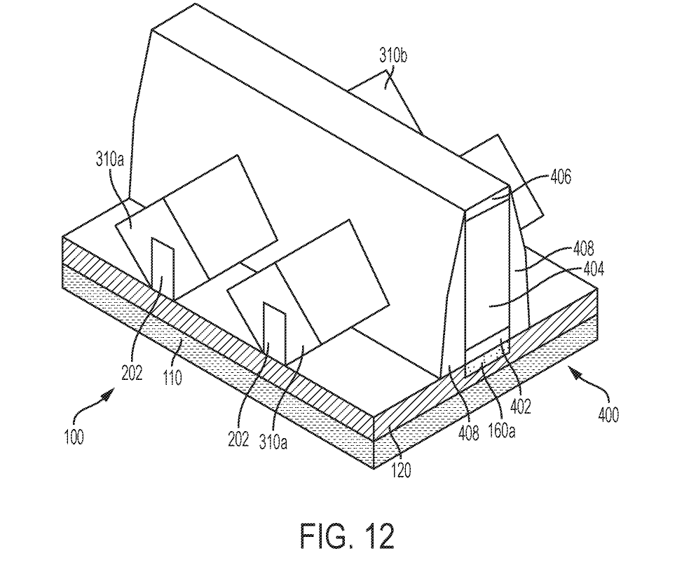

Referring to FIG. 12, fins 202 may be etched (i.e., patterned) from the semiconductor layer 130 of the substrate 100. In certain embodiments, fins 202 are formed from a crystalline semiconductor material. The semiconductor material forming fins 202 may be doped, undoped, or contain doped and undoped regions therein. Each doped region within the semiconductor fins 202 may have the same or different doping concentrations and/or conductivities. Doped regions that are present can be formed, for example, by an ion implantation process or by gas phase doping.

Each fin has a height (H) that may range from 10 nm to 100 nm and a width (W) that may range from 4 nm to 30 nm. Other heights and widths that are less than or greater than the ranges mentioned can also be used. In structures comprising plural fins, each fin may be spaced apart from its nearest neighbor by a pitch (i.e., repeat distance) of 20 nm to 100 nm. Such plural fins are typically oriented parallel to each other. Plural fins may have identical or substantially identical dimensions, i.e., height and/or width. As used herein, substantially identical dimensions vary by less than 10%, e.g., less than 5%, 2% or 1%. As shown in FIG. 12, each fin 202 has a bottom surface that is disposed directly on a top surface of the insulator layer 120.

Epitaxial source and drain raised active regions 310a, 310b are formed over the fins 202 at opposing ends thereof, while a gate stack 400 is formed over the fins 202 defining a channel region between the source and drain regions. Gate stack 400 includes a gate dielectric 402, a gate conductor 404, and a gate cap 406. Gate stack 400 is formed generally orthogonal to the length-wise dimension of the fins 202 such that gate dielectric 402 and gate conductor 404 straddle the fins.

Gate dielectric 402 may comprise silicon oxide, silicon nitride, silicon oxynitride, a high-k dielectric, or other suitable material. As used herein, a high-k material has a dielectric constant greater than that of silicon oxide. A high-k dielectric may include a binary or ternary compound such as hafnium oxide (HfO₂).

A gate conductor 404 is formed over the gate dielectric 402, and a gate cap 406 is formed over the gate conductor 404. The gate conductor 404 may include a conductive material such as polysilicon, silicon-germanium, a conductive metal such as Al, W, Cu, Ti, Ta, W, Pt, Ag, Au, Ru, Ir, Rh and Re, alloys of conductive metals, e.g., Al—Cu, silicides of a conductive metal, e.g., W silicide, and Pt silicide, or other conductive metal compounds such as TiN, TiC, TiSiN, TiTaN, TaN, TaAlN, TaSiN, TaRuN, WSiN, NiSi, CoSi, as well as combinations thereof. The gate conductor 404 may comprise one or more layers of such materials such as, for example, a metal stack including a work function metal layer and/or a liner.

Sidewall spacers 408 may be formed on the sides of the gate stack 400. The gate spacers 408 can be formed around the gate stack 402, 404, 406. The gate spacers 408 can be formed, for example, by depositing a conformal dielectric material layer on the plurality of semiconductor fins 202 and the gate stack, and anisotropically etching the conformal dielectric layer.

According to various embodiments, the substrate used to support the device architecture is a semiconductor-on-metallic-doped insulator (SOMDI) substrate. The metallic atom or metallic compound-doped substrate exhibits enhanced thermal conduction properties. For instance, the gate conductor of the device can be located at least partially over a doped region in order to enhance heat dissipation away from the gate conductor. The dopant profile within the buried oxide layer of the substrate may be engineered to conduct and remove heat without negatively impacting the electrical properties of the substrate in order to preserve device performance.

For instance, upper regions of the isolation layer of an example SOMDI substrate may be doped locally proximate to semiconductor fins that are defined over the isolation layer to provide thermal conduction while retaining sufficient electrical isolation between the fins and the semiconductor substrate. Lower regions of the isolation layer, spaced away from the fins, may be doped globally to enhance the thermal conductivity of the isolation layer.

As used herein, the singular forms “a,” “an” and “the” include plural referents unless the context clearly dictates otherwise. Thus, for example, reference to a “dopant” includes examples having two or more such “dopants” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

As used herein, an element such as a layer or region that is “on” or “over” or “disposed over” a substrate or other layer refers to formation above, or in contact with, a surface of the substrate or layer. For example, where it is noted or recited that a layer is disposed over a substrate or other layer, it is contemplated that intervening structural layers may optionally be present between the layer and the substrate. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to an oxide layer that comprises silicon dioxide include embodiments where an oxide layer consists essentially of silicon dioxide and embodiments where an oxide layer consists of silicon dioxide.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A semiconductor-on-insulator (SOI) substrate, comprising:
a handle portion;
an isolation layer disposed over the handle portion; and
a semiconductor layer disposed over the isolation layer and defining an interface boundary with the isolation layer, wherein the isolation layer comprises a dopant selected from the group consisting of C, Si, Ge Ta, W, Mo, SiC, AlN and TaSi, and wherein the dopant defines a doped region that extends from the interface boundary partially through the isolation layer.

2. (canceled)

3. The semiconductor-on-insulator substrate of claim 1, wherein the dopant defines a doped region that extends from the interface boundary to a first depth of the isolation layer.

4. The semiconductor-on-insulator substrate of claim 1, wherein the dopant defines a buried doped region that extends from a first depth of the isolation layer to a second depth of the isolation layer greater than the first depth.

5. The semiconductor-on-insulator substrate of claim 1, wherein the dopant defines a plurality of doped regions that extend from the interface boundary to a first depth of the isolation layer.

6. The semiconductor-on-insulator substrate of claim 5, wherein the dopant further defines a buried doped region that extends from a second depth of the isolation layer greater than the first depth to a third depth of the isolation layer greater than the second depth.

7. The semiconductor-on-insulator substrate of claim 6, wherein the dopant within the plurality of doped regions is different than the dopant within the buried doped region.

8. The semiconductor-on-insulator substrate of claim 5, wherein the dopant further defines a plurality of buried doped regions that extend from a second depth of the isolation layer greater than the first depth to a third depth of the isolation layer greater than the second depth.

9. The semiconductor-on-insulator substrate of claim 1, wherein the dopant defines a plurality of buried doped regions that extend from a first depth of the isolation layer to a second depth of the isolation layer greater than the first depth.

10. A FinFET device disposed on the semiconductor-on-insulator substrate of claim 1.

11. A FinFET device disposed on the semiconductor-on-insulator substrate of claim 5, wherein the device comprises a gate conductor located at least partially over one of the plurality of doped regions.

12. A FinFET device disposed on the semiconductor-on-insulator substrate of claim 6, wherein the device comprises a gate conductor located at least partially over one of the plurality of doped regions.

13. A FinFET device comprising:
a semiconductor fin on a semiconductor-on-insulator substrate, the semiconductor-on-insulator substrate comprising an isolation layer and a semiconductor layer over the isolation layer, the semiconductor layer defining an interface boundary with the isolation layer, wherein the semiconductor fin is disposed over the isolation layer of the substrate, and the semiconductor fin includes a pair of source/drain regions separated by a channel region;
a gate dielectric layer disposed over the channel region; and
a gate conductor layer disposed over the gate dielectric layer, wherein the isolation layer comprises a dopant, and wherein the dopant defines a doped region that underlies the gate conductor layer and extends from the interface boundary partially through the isolation layer.

14. The FinFET device of claim 13, wherein at least one of the gate conductor layer and the pair of source/drain regions at least partially overlie a doped region within the isolation layer.

15. The FinFET device of claim 13, wherein the gate conductor layer overlies a doped region within the isolation layer.

16. A method of manufacturing a semiconductor-on-insulator (SOI) substrate comprising:
forming an isolation layer over a handle portion of a semiconductor substrate;
forming a semiconductor layer over the isolation layer; and
incorporating a dopant into the isolation layer, wherein the doped isolation layer exhibits a thermal conductivity greater than that of an undoped isolation layer.

17. The method of claim 16, wherein incorporating the dopant comprises ion implanting the dopant into the isolation layer.

18. The method of claim 17, further comprising forming a patterned masking layer over the semiconductor layer prior to the ion implanting.

19. The semiconductor-on-insulator substrate of claim 1, wherein a concentration of the dopant varies as a function of the isolation layer thickness.

20. The semiconductor-on-insulator substrate of claim 1, wherein the dopant is incorporated into the isolation layer by ion implantation or gas phase doping.
